(19) United States
(12) Patent Application Publication
(10) Pub. No.: US 2011/0111962 A1
(43) Pub. Date: May 12, 2011

(54) IMPROVEMENTS IN MAGNESIUM DIBORIDE SUPERCONDUCTORS AND METHODS OF SYNTHESIS

(75) Inventors: Xiaolin Wang, New South Wales (AU); Shi Xue Dou, New South Wales (AU); Md. Shahriar Al Hossain, New South Wales (AU); Zhenxiang Cheng, New South Wales (AU)

(73) Assignee: University of Wollongong, WOLLONGONG (AU)

(21) Appl. No.: 12/670,259

(22) PCT Filed: Jul. 23, 2007
(86) PCT No.: PCT/AU2007/001020

§ 371 Date: Nov. 22, 2010

(51) Int. Cl. H01L 39/12; H01L 39/24; C01B 35/04

(52) U.S. Cl. 505/122; 505/100; 505/500; 423/289

(57) ABSTRACT

Improved magnesium diboride superconducting materials and methods of synthesis are disclosed. Embodiments of the superconducting material comprise at least two starting materials capable of forming MgB₂ and at least one dopant compound comprising silicon, carbon, hydrogen and oxygen. The starting materials and the at least one dopant compound are heated and mixed at an atomic level to produce a silicon-doped MgB₂ superconducting material. Examples of the dopant compound include silicone oil, Triacetoxy(methyl)silane (2), 1,7-Dichloro-octamethyltetrasiloxane (2) and Tetramethyl orthosilicate (6).

### FIELD OF THE INVENTION

The present invention relates to superconducting materials and methods of synthesis thereof. In particular, the present invention relates to doped superconducting materials comprising magnesium diboride (MgB₂) and methods of synthesis thereof.

### BACKGROUND TO THE INVENTION

Superconductors have two important characteristics distinguishing them from other materials such as semiconductors, metallic conductors etc. One is losing their resistance and the other is repelling magnets or magnetic fields or levetating above magnets when they are in a superconducting state. Therefore, superconductors have significant applications as superconducting cables being able carrying very large electric currents without energy loss, and as superconducting magnets producing much higher magnetic fields than conventional electromagnets.

For a material to exhibit superconducting behaviour, the material must be cooled below its critical temperature (T_{c}), the current passing through the cross-section of the material must be below the critical current density (J_{c}) and the magnetic field to which the material is exposed must be below the critical magnetic field (H_{c}). Magnesium diboride (MgB₂) is a superconductor with a much higher superconducting transition temperature (T_{c}) of 40 K and lower cost than conventional low temperature superconductors (T_{c}<25 K) and is of great potential for large-scale and microelectronic applications at temperatures far above that of liquid helium (T=4.2 K).

For practical applications that require carrying large supercurrents in the presence of magnetic fields, improvements in the critical current density (J_{c}), the upper critical field (H_{c2}), and the irreversibility field (Hᵢᵣᵣ) have been the key topics of research on MgB₂ superconductors. An effective way to improve the flux pinning is to introduce flux pinning centres into MgB₂. It has been found that chemical doping with non-magnetic materials appears to be the most suitable approach to increase the ability of MgB₂ to carry large currents for practical applications. A number of additives have been examined for J_{c}, H_{c2}, and Hᵢᵣᵣ improvements. It has already been shown that a J_{c} enhancement by more than one order of magnitude in high magnetic fields can be easily achieved with only a slight reduction in T_{c} through doping MgB₂ with nanoparticles, such as SiC, Si, and C. It has also been shown that SiC doping significantly enhances the H_{c2} and Hᵢᵣᵣ in polycrystalline bulks, as well as in wires and tapes.

For C doping, high sintering temperatures are required to allow the C to readily substitute for B. The partial replacement of B by C is believed to be responsible for the enhancement of H_{c2} and flux pinning in MgB₂ according to the two band scattering model. However, a low sintering temperature is much more desirable for practical applications. Its advantages include reducing the reaction between metal sheath materials and MgB₂, lower fabrication costs and making finer MgB₂ grains. Nano-SiC or Si doping can effectively enhance the flux pinning in MgB₂ even when the samples are processed at temperatures as low as around 600° C.

The improvement of flux pinning enhancement is controlled by the sizes of the particles doped into the MgB₂. However, the requirement for finer nanoparticles brings some dilemmas, such as higher cost and some technical problems in fabricating the much finer nanoparticles. Because the nanoparticles are in solid state form, another problem is agglomeration of nanoparticles, which limits the homogeneity of mixing with MgB₂. This homogeneity of mixing is very crucial in determining the flux pinning ability for MgB₂ made by the in-situ reaction method. Recently, it has been reported that aromatic hydrocarbon addition to MgB₂ can enhance the flux pinning in MgB₂ at low sintering temperatures. However, the enhancement is not greater than in nano-SiC doped samples, and this organic solvent is very volatile at ambient pressure.

In addition, solid state malic acid addition into MgB₂ has also been reported to enhance the flux pinning in MgB₂. However, the sintering temperature used was as high as 900° C. for 30 min.

Hence, there are one or more deficiencies in the known low temperature superconductor materials incorporating MgB₂. Because of the commercial appeal of superconductors comprising MgB₂ there is a need to address or at least ameliorate one or more of these deficiencies or provide a suitable commercial alternative thereto.

In this specification, the terms “comprises”, “comprising” or similar terms are intended to mean a non-exclusive inclusion, such that a method, system or apparatus that comprises a list of elements does not include those elements solely, but may well include other elements not listed.

### SUMMARY OF THE INVENTION

In one form, although it need not be the only or indeed the broadest form, the invention resides in a superconducting material comprising:

at least two starting materials capable of forming MgB₂; and at least one dopant compound comprising silicon, carbon, hydrogen and oxygen;

wherein the starting materials and the at least one dopant compound are heated and mixed at an atomic level to produce a silicon-doped MgB₂ superconducting material.

Suitably, the MgB₂ superconducting material further comprises one or more of the following in the MgB₂ lattice: carbon doping; oxygen doping.

Preferably, the at least one dopant compound is a liquid, but may also be a solid.

Suitably, the at least one dopant compound is a siloxane and is in the form of silicone oil (—SiC₂H₆O—)ₙ.

Suitably, the at least one dopant compound includes, but is not limited to, one or more of the following: Triacetoxy(methyl)silane (2); (CH₃CO₂)₃SiCH₃; 1,7-Dichloro-octamethyltetrasiloxane (2) C₈H₂₄Cl₂O₃Si₄; Tetramethyl orthosilicate (6) Si(OCH₃)₄.

In another form, although again not necessarily the broadest form, the invention resides in a superconducting material comprising:

at least two starting materials capable of forming MgB₂; and

at least one dopant compound comprising silicon, carbon and hydrogen;

wherein the starting materials and the at least one dopant compound are mixed at an atomic level and heated to produce oxygen or an oxygen-containing compound at an intermediate stage and a silicon-doped MgB₂ superconducting material.

Suitably, the at least one organic dopant compound includes, but is not limited to, one or more of the following: Tetrakis(trimethylsilyl)silane (1), [(CH₃)3Si]4Si, which sublimes to produce CO, CO₂ and SiO₂ in air; Hexamethyldisilane (1), (Si(CH₃)3)2; Tetraethylsilane (2) Si(C₂H₅)4.

In another form, although again not necessarily the broadest form, the invention resides in a method of synthesizing a superconducting material including:

a) mixing at least two starting materials capable of forming MgB₂ with at least one dopant compound comprising silicon, carbon, hydrogen and oxygen; and

b) heating the mixed materials such that the at least two starting materials and the at least one dopant compound react at an atomic level to produce a silicon-doped MgB₂ superconducting material.

Suitably, the at least one dopant compound represents ≦30 wt % of MgB₂ and in some embodiments represents 3, 10, 15, 20, or 30 wt % of MgB₂.

Further forms and features of the present invention will become apparent from the following detailed description.

### BRIEF DESCRIPTION OF THE DRAWINGS

By way of example only, preferred embodiments of the invention will be described more fully hereinafter with reference to the, accompanying drawings, wherein:

FIG. 1 is a general flow diagram showing a method of synthesizing a superconducting material in accordance with embodiments of the present invention;

FIG. 2 is an X-ray diffraction pattern for an embodiment of the superconducting material with the variation of the a and c lattice parameters with doping level shown in the inset;

FIG. 3 shows resistance versus temperature (R-T) curves for embodiments of the superconducting material with further detail shown in the insets;

FIG. 4 is a graph showing the magnetic field dependence of the critical current density at different temperatures for embodiments of the superconducting material;

FIG. 5 shows graphs illustrating the variation in upper critical field and irreversibility field as a function of normalized temperature for different levels of doping according to embodiments of the superconducting material;

FIG. 6 is a graph illustrating the field dependence of the volume pinning force at 20K for embodiments of the superconducting material; and

FIG. 7 is a graph showing the full width at half maximum (FWHM) of various diffraction peaks as a function of the doping level in accordance with embodiments of the superconducting material.

### DETAILED DESCRIPTION OF THE INVENTION

To solve the aforementioned problem of nanoparticle agglomeration, embodiments of the present invention use precursors, preferably in liquid form, that contain at least Si and C that are able to introduce both Si and C into MgB₂ at an atomic scale, even when the sintering time is short and at low temperatures.

According to one embodiment, the starting materials capable of forming the superconducting material MgB₂ are amorphous boron powder with a purity of 99.9% and Mg powder with a purity of 99%. These are mixed with a dopant compound comprising silicon, carbon, hydrogen and oxygen in the form of commercial, high temperature silicone oil from Sigma Aldrich. Commercial silicone oil, (—SiC₂H₆O—)ₙ, is a colourless, odourless, chemically inert lubricant, with excellent thermal stability.

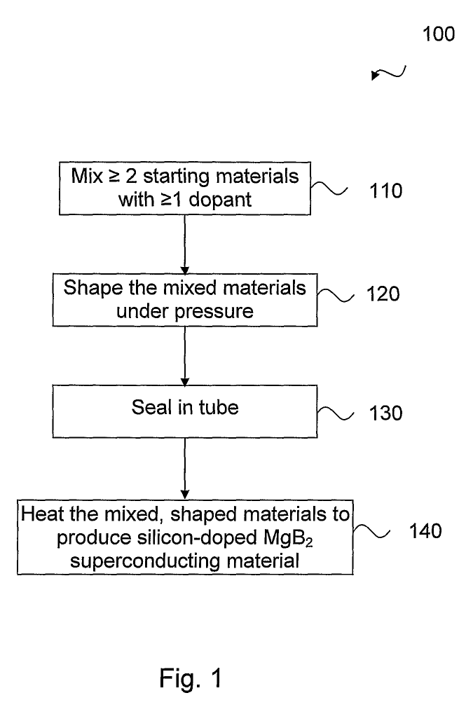

With reference to the method 100 of synthesizing embodiments of the superconducting material shown in FIG. 1, at 110 the B and Mg powders at chemical stoichiometry are thoroughly mixed with diluted silicone oil in acetone. A range of samples with different doping levels were produced. The amounts of silicone oil added into the MgB₂ samples were 3, 10, 15, 20, and 30 wt %. At 120, the samples were shaped into pellets 13 mm in diameter and 2 mm in thickness under uniaxial pressure. At 130, these pellets were then sealed in an iron tube and at 140 sintered in a tube furnace at 750-780° C. for 10 min only. It has been found that short sintering is as good as long sintering in terms of flux pinning for MgB₂. A high purity argon gas flow was maintained throughout the in situ sintering process to avoid oxidation. An undoped MgB₂ sample was also prepared under the same in situ processing conditions as a reference sample.

It will be appreciated that the aforementioned method is for experimentation purposes. For commercial applications, known powder in tube wire drawing techniques can be employed to produce superconducting wires in accordance with embodiments of the superconducting material described herein. Other known techniques can be employed to produce the superconducting material in other shapes, such as tapes and in bulk.

From x-ray diffraction (XRD) experiments, it was observed that all the samples crystallized in the MgB₂ structure as the major phase. Slight amounts of MgO and Mg₂Si are also present in the silicone oil doped samples. The amount of Mg₂Si is increased by increasing the silicone oil content. However, the tiny amount of MgO phase remains the same for the undoped sample and all the doped samples as determined by XRD.

The decomposition of pure commercial silicone oil possibly follows the following reaction at 800° C.:

(—SiC₂H₆O—)ₙ→SiO+2C+3H₂→SiC+CO.

The aforementioned decomposition of silicone oil took place below 800° C. because all the samples were sintered at 780° C. Si and C released as a result of the decomposition of the silicone oil may not form SiC, as no detectable SiC phase was observed from the XRD patterns. It is believed that the chemically active Mg reacted with Si and that this caused the decomposition of silicone oil at relatively low temperatures. The remaining C would then embed itself into the MgB₂ grains together with Mg₂Si and also substitute into B sites in the MgB₂ crystal lattice, as has been observed in nano-SiC, Si, and C doped MgB₂.

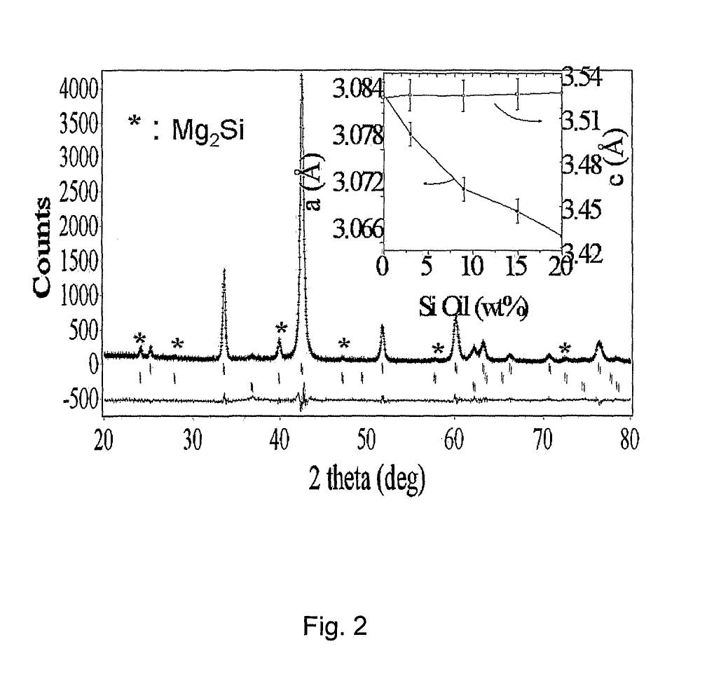

The calculated XRD patterns using Rietveld refinement fit very well with the observed patterns. The refined and observed XRD patterns for the 10 wt % silicone oil added sample are shown in FIG. 2 with the variation of the a and c lattice parameters with doping level shown in the inset. (The arrows in the inset point to the respective lattice parameter.) The lattice parameters obtained by the refinement revealed that the a lattice parameter is reduced from 3.085 to 3.065 Å for the pure and 15 wt % silicone oil doped samples, respectively, while the c lattice parameter is only slightly increased, as illustrated in the inset.

The significant reduction in the a lattice parameter indicates that carbon has been doped into the B sites in the crystal lattice and caused the reduction in T_{c}. Both C doping and the inclusion of Mg₂Si can enhance the electron scattering, as proved by the decreased residual resistivity ratio (RRR) values, and, in turn, enhance the flux pinning.

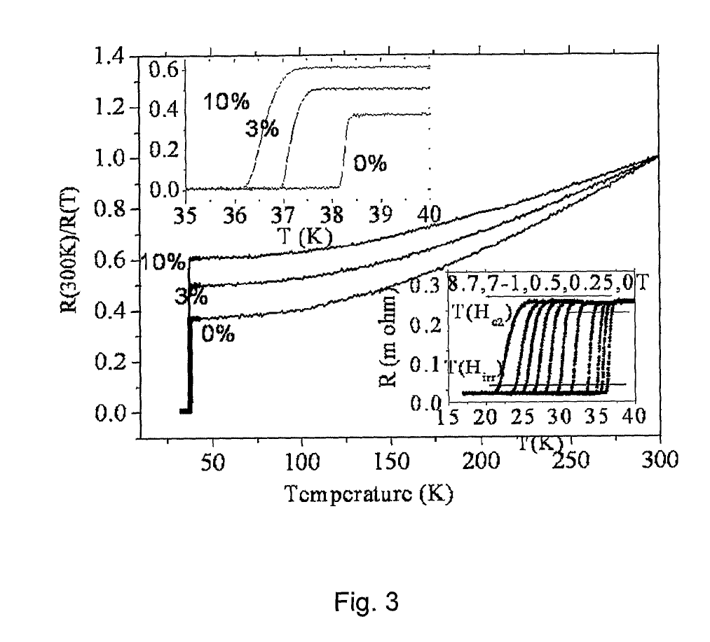

FIG. 3 shows the resistance versus temperature curves (R-T) for three samples at zero external magnetic field over a temperature range of 30-300 K. It can be seen that the scattering increases with increasing silicone oil content. The resistivity at 40 K increases from 24 μΩ cm for the pure MgB₂ to 64 μΩ cm for the 10 wt % silicone oil doped MgB₂. The T_{c} values and residual resistivity ratios, R(300K)/R(Tc), were obtained to be 38.2K, 37K, and 36.2 K and 2.72, 2.0, and 1.67, for the 0 wt %, 3 wt %, and 10 wt % silicone oil samples, respectively.

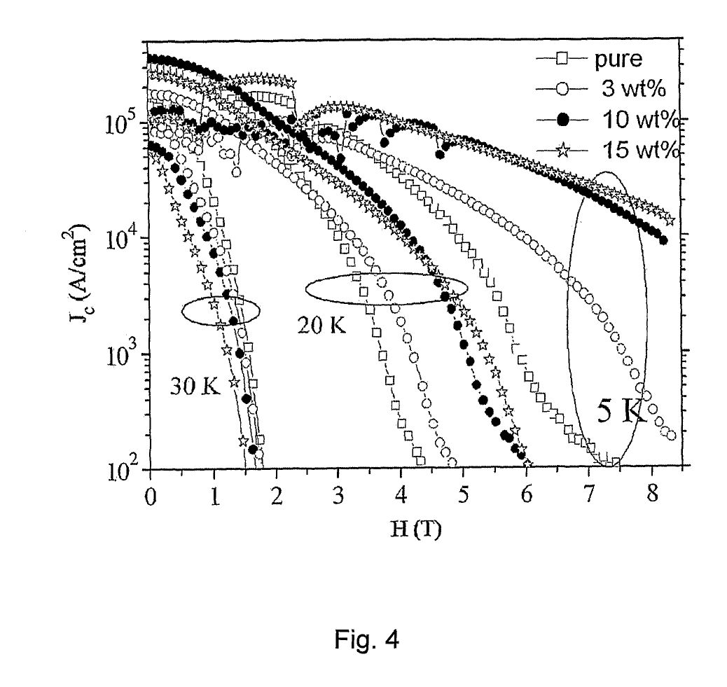

The magnetic field dependence of J_{c} at 30, 20, and 5 K is shown in FIG. 4. It should be noted that the J_{c} values in high fields are significantly enhanced for all the doped samples. The J_{c} of the un-doped sample dropped to 100 A/cm² at 7 T and 5 K. However, the J_{c} values at the same field are increased by more than one or two orders of magnitude for the 3, 10, and 15 wt % silicone oil added samples. At 8 T and 5 K, the Jc values of the 10 and 15 wt % doped samples are over (1-2)×10⁴ A/cm², more than one order of magnitude higher than for the 3 wt % doped sample. It should also be noted that there was no degradation in self-field J_{c} values for the 10 and 15 wt % silicone oil doped samples.

The H_{c2} and Hᵢᵣᵣ were also enhanced, as proved by the data determined from the R-T curves, which are shown in the inset of FIG. 3. The inset shows the resistance versus temperature (R-T) measured at different applied magnetic fields up to 8.7 T for the 10 wt % doped sample.

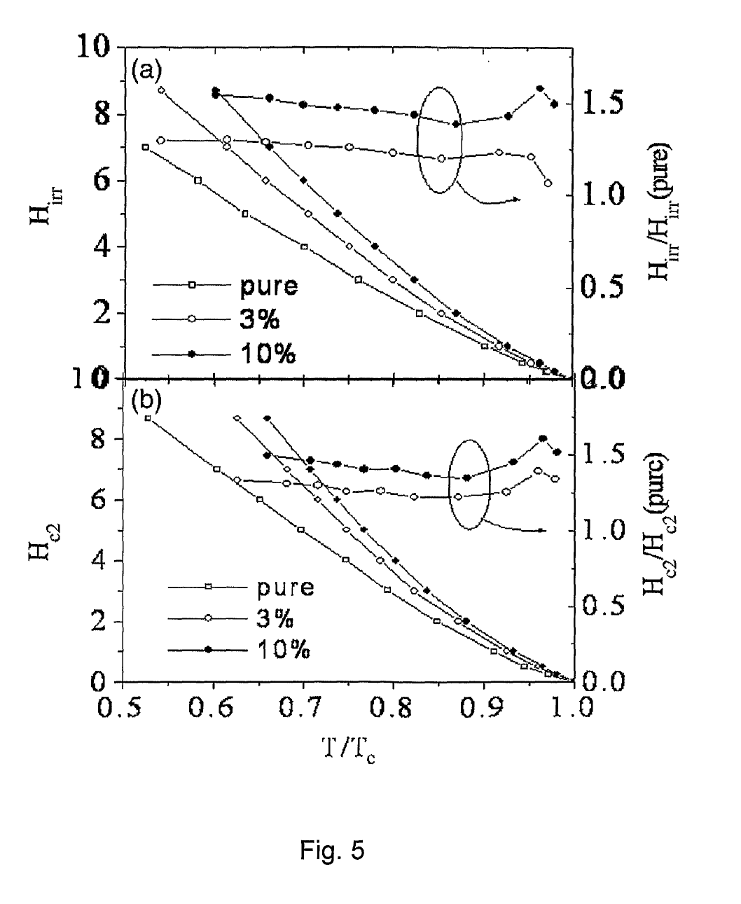

The H_{c2} values versus normalized temperature T/T_{c} obtained from the 90% or 10% values of their corresponding resistive transitions are shown in FIG. 5. The H_{c2} values of the undoped sample are also included for comparison. Significantly enhanced Hᵢᵣᵣ and H_{c2} for the silicone oil doped sample are clearly observed. It can be seen that the H_{c2} curves of all the samples show a positive curvature near T_{c} as a result of the two band superconductivity in MgB₂. Also, all the doped samples have larger dH_{c2}/d(T/Tc) values compared to the undoped sample. The evolution of the enhancement of flux pinning is shown clearly in the variation of the ratio r(Hᵢᵣᵣ)=Hᵢᵣᵣ(doped)/Hᵢᵣᵣ(undoped) or r(H_{c2})=H_{c2}(doped)/H_{c2}(undoped) with T/T_{c}. (The arrows in FIG. 5 point to the respective axes for these variations.) Both ratios are about 1.25 and 1.5 for the 3 wt % and the 10 wt % silicone oil doped MgB₂, respectively. The above results reveal that MgB₂ with silicone oil added exhibits higher Hᵢᵣᵣ values compared to the undoped samples that were processed under the same fabrication conditions.

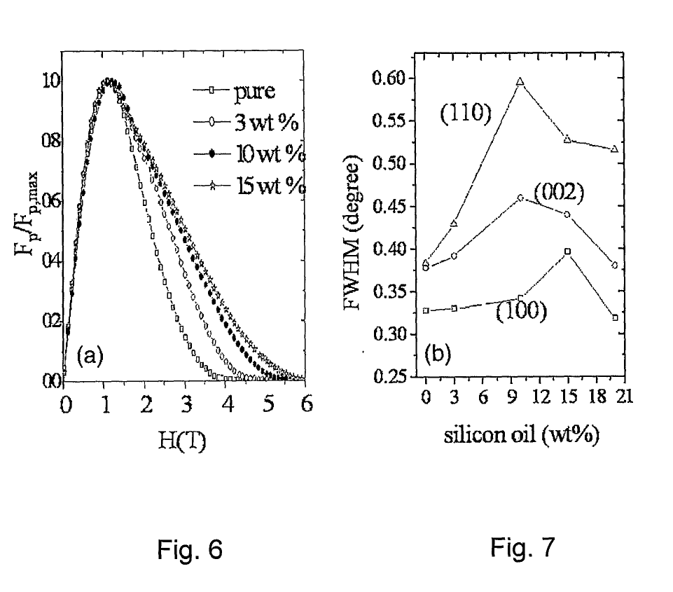

The field dependence of the normalized volume pinning force Fₚ=J×B at 20 K for all the samples is shown in FIG. 6. It can be seen that the pinning force for the silicone oil added samples is significantly higher than for the undoped sample at B>1.5 T. The XRD diffraction peaks are observed to broaden with an increasing amount of silicone oil. FIG. 7 shows the full width at half maximum (FWHM) for the (100), (002), and (110) peaks for all the samples. It can be seen that the values of the FWHM of the (100) peak increase monotonically for all samples with an amount of Si oil up to 15 wt %. The FWHM values also increase for the (002) and (110) peaks for the 3 and 10 wt % silicone oil samples. The peak broadening in these samples likely arises from non-uniform strain that is mainly caused by C doping on B sites. The grain sizes, which could also affect the peak width, have been observed to be very similar under scanning electron microscopy. However, a further study on the grain sizes and crystal defects using high resolution transmission electron microscopy is needed. The presence of Mg₂Si impurity phase is also responsible for the peak broadening, as the Mg₂Si is believed to act as a grain refiner in MgB₂. Therefore, the enhanced flux pinning, H_{c2}, Hᵢᵣᵣ, and J_{c}(H) observed in our silicone oil added MgB₂ are due to the C-doping effect and inclusions of Mg₂Si. It is believed that the large distortion of the crystal lattice caused by both carbon substitution for B and inclusion of Mg₂Si leads to enhanced electron scattering and enhancement of H_{c2}.

The data on SiC nanopowder added MgB₂ prepared using a hot pressing method presented in our previous work are better than what we have achieved in this work using Si oil. However, it is easier and cheaper to enhance the flux pinning with Si oil compared to using SiC nanopowders. Further improvement of the flux pinning performance of MgB₂ using Si oil is highly possible by optimizing the processing conditions.

In summary, it has been found that a significant flux pinning enhancement in MgB₂ can be easily achieved using a liquid additive, silicone oil. The results showed that Si and C released from the decomposition of the silicone oil formed Mg₂Si and substituted into the B sites, respectively. Increasing the amount of Si oil up to 15 wt % leads to the reduction of the lattice parameters, as well as T_{c} and R(300 K)/R(T_{c}) values, resulting in a significant enhancement of J_{c}(H), Hᵢᵣᵣ, and H_{c2}.

In alternative embodiments, the starting materials capable of forming MgB₂ can include one or more powders of the following MgB₂, MgH₂, MgB₄. It is also envisaged that flux pinning enhancement and enhancement of J_{c}(H), Hᵢᵣᵣ, and H_{c2} can also be achieved with lower purity starting materials.

Although the dopant compound in the aforementioned embodiments is a liquid, in alternative embodiments, the dopant can be a solid or a powder, which is dissolved in a solvent, such as acetone, toluene, hexane, benzene or other solvent.

In alternative embodiments, a sintering temperature of about 600-1000° C. and a sintering time of about a few minutes up to about 24 hours can be employed.

In other embodiments, other dopant compounds comprising silicon, carbon, hydrogen and oxygen can be employed, which can be in the form of, for example, other siloxanes, such as, but not limited to, 1,7-Dichloro-octamethyltetrasiloxane (2) C₈H₂₄Cl₂O₃Si₄ and can be polymerized siloxanes.

In further embodiments, the dopant compound can be a silane, such as, but not limited to, Triacetoxy(methyl)silane (2); (CH₃CO₂)₃SiCH₃ or a silicate, such as, but not limited to, Tetramethyl orthosilicate (6) Si(OCH₃)₄.

In other embodiments, the dopant compound comprises silicon, carbon and hydrogen. In accordance with embodiments of the present invention, when one or more such dopant compounds are mixed with the starting materials capable of forming MgB₂ and heated to mix the constituents at an atomic level, as described in the aforementioned method, oxygen, or one or more oxygen-containing compounds, are produced at an intermediate stage, to ultimately produce a silicon-doped MgB₂ superconducting material. For example, the organic dopant compound can include, but is not limited to, one or more of the following: Tetrakis(trimethylsilyl)silane (1), [(CH₃)3Si]4Si, which sublimes to produce CO, CO₂ and SiO₂ in air, Hexamethyldisilane (1), (Si(CH₃)3)2 or Tetraethylsilane (2) Si(C₂H₅)4. Silicon-doped MgB₂ superconducting materials produced using one or more of the alternative dopants recited above are also likely to exhibit C-doping effects and inclusions of Mg₂Si to provide flux pinning enhancement and enhancement of J_{c}(H), Hᵢᵣᵣ, and H_{c2}.

In yet further embodiments, instead of one or more of the aforementioned organic dopant compounds being employed to produce a doped MgB₂ superconducting material, the dopant compound can include, but is not limited to, one or more of the following: SiCl₄, Sil₄, CCl₄, Cl₄, fine Si, SiO₂, SiC.

Hence, the superconducting materials and methods of synthesis of the present invention address the agglomeration problem of the prior art because silicone oil and the other dopants referred to herein are liquids or are diluted in a solvent this enabling the dopant to mix with the starting materials and thus with MgB₂ very homogeneously. Only a small reduction in T_{c} compared to some of the prior art dopants is observed, whilst enhanced flux pinning and J_{c}(H), Hᵢᵣᵣ, and H_{c2} values are observed. The dopants described herein are cheaper than nano-SiC and CNTs and easier to work with and can produce superior MgB₂ superconducting materials at lower temperatures.

Throughout the specification the aim has been to describe the invention without limiting the invention to any one embodiment or specific collection of features. Persons skilled in the relevant art may realize variations from the specific embodiments that will nonetheless fall within the scope of the invention.

1. A superconducting material comprising:
at least two starting materials capable of forming MgB₂; and
at least one dopant compound comprising silicon, carbon, hydrogen and oxygen;
wherein the starting materials and the at least one dopant compound are heated and mixed at an atomic level to produce a silicon-doped MgB₂ superconducting material.

2. The superconducting material of claim 1, further comprising one or more of the following in the MgB₂ lattice: carbon doping; oxygen doping.

3. The superconducting material of claim 1, wherein the at least one dopant compound is a liquid.

4. The superconducting material of claim 1, wherein the at least one dopant compound is a siloxane.

5. The superconducting material of claim 4, wherein the siloxane is polymerized.

6. The superconducting material of claim 1, wherein the at least one dopant compound is silicone oil (—SiC₂H₆O—)ₙ.

7. The superconducting material of claim 1, wherein the at least one dopant compound includes one or more of the following:
Triacetoxy(methyl)silane (2); (CH₃CO₂)₃SiCH₃; 1,7-Dichloro-octamethyltetrasiloxane (2) C₈H₂₄Cl₂O₃Si₄; Tetramethyl orthosilicate (6) Si(OCH₃)₄.

8. The superconducting material of claim 1, wherein the at least one dopant compound represents ≦30 wt % of MgB₂.

9. The superconducting material of claim 1, wherein the at least one dopant compound represents 3, 10, 15, 20, or 30 wt % of MgB₂.

10. A superconducting material comprising:
at least two starting materials capable of forming MgB₂; and
at least one dopant compound comprising silicon, carbon and hydrogen;
wherein the starting materials and the at least one dopant compound are mixed at an atomic level and heated to produce oxygen or an oxygen-containing compound at an intermediate stage and a silicon-doped MgB₂ superconducting material.

11. The superconducting material of claim 10, comprising one or more of the following in the MgB₂ lattice: carbon doping; oxygen doping.

12. The superconducting material of claim 10, wherein the at least one dopant compound includes, one or more of the following:
Tetrakis(trimethylsilyl)silane (1), [(CH₃)3Si]4Si; Hexamethyldisilane (1), (Si(CH₃)3)2; Tetraethylsilane (2) Si(C₂H₅)4.

13. The superconducting material of claim 10, wherein the at least one dopant compound represents ≦30 wt % of MgB₂.

14. The superconducting material of claim 10, wherein the at least one dopant compound represents 3, 10, 15, 20, or 30 wt % of MgB₂.

15. A method of synthesizing a superconducting material including:
a) mixing at least two starting materials capable of forming MgB₂ with at least one dopant compound comprising silicon, carbon, hydrogen and oxygen; and
b) heating the mixed materials such that the at least two starting materials and the at least one dopant compound react at an atomic level to produce a silicon-doped MgB₂ superconducting material.

16. The method of claim 15, further including heating the mixed materials for about several minutes up to 24 hours.

17. The method of claim 15, further including heating the mixed materials at 600-1000° C.

18. The method of claim 15, further including dissolving the at least one dopant compound in acetone, toluene, hexane, benzene or other solvent.

19. The method of claim 15, wherein the at least one dopant compound includes one or more of the following: a siloxane;
Triacetoxy(methyl)silane (2); (CH₃CO₂)₃SiCH₃; 1,7-Dichloro-octamethyltetrasiloxane (2) C₈H₂₄Cl₂O₃Si₄; Tetramethyl orthosilicate (6) Si(OCH₃)₄.

20. A method of synthesizing a superconducting material including:
a) mixing at least two starting materials capable of forming MgB₂ with at least one dopant compound comprising silicon, carbon and hydrogen; and
b) heating the mixed materials such that the at least two starting materials and the at least one dopant compound react at an atomic level to produce oxygen or an oxygen-containing compound at an intermediate stage and a silicon-doped MgB₂ superconducting material.

21. The method of claim 20, wherein the at least one dopant compound includes one or more of the following: Tetrakis(trimethylsilyl)silane (1), [(CH₃)3Si]4Si; Hexamethyldisilane (1), (Si(CH₃)3)2; Tetraethylsilane (2) Si(C₂H₅)4.

22. The method of claim 20, further including heating the mixed materials for about several minutes up to 24 hours.

23. The method of claim 20, further including heating the mixed materials at 600-1000° C.

24. The method of claim 20, further including dissolving the at least one dopant compound in acetone, toluene, hexane, benzene or other solvent.
